(19) United States
(12) Patent Application Publication
(10) Pub. No.: US 2026/0171794 A1
(43) Pub. Date: Jun. 18, 2026

(54) RECHARGEABLE ELECTRICAL ENERGY STORAGE

(71) Applicant: TRANSTEX LLC, Indianapolis, IN (US)

(72) Inventors: Suryanarayana Chowdary GUNNAM, Saint Charles, MO (US); Kadir EFECIK, Richmond Heights, MO (US); Robert LATTIN, Maryland Heights, MO (US)

(73) Assignee: TRANSTEX LLC, Indianapolis, IN (US)

(21) Appl. No.: 19/174,657

(22) Filed: Apr. 9, 2025

Related U.S. Application Data
(60) Provisional application No. 63/735,699, filed on Dec. 18, 2024.

(51) Int. Cl. H02J 1/10; G01R 31/382; H01M 10/44

(52) U.S. Cl. CPC H02J 1/10; G01R 31/382; H01M 10/441; H01M 2220/20; H02J 2105/33

(57) ABSTRACT

The present document describes an auxiliary electrical energy storage system for a vehicle such as a semi-truck comprising a main electric energy storage component (main EESC), an ICE, an alternator, and accessory components generating an auxiliary load. The auxiliary electrical energy storage system has an auxiliary EESC; a DC/DC converter electrically coupled to the main EESC, the auxiliary EESC, the alternator, and the accessory components; and a controller coupled to the DC/DC converter, controlling flow of energy in and out of the EESC's. Such system allows to power the auxiliary load when the vehicle is in an idle state.

### CROSS-REFERENCE TO RELATED APPLICATION

This application relates to and is a non-provisional application claiming priority under 35 U.S.C. §119(e) and 37 C.F.R. §1.78(a) for a priority claim to earlier-filed provisional applications Ser. No. 63/735,699, filed Dec. 18, 2024, under 35 U.S.C. §111, entitled RECHARGEABLE ELECTRICAL ENERGY STORAGE, the specification of which is hereby incorporated herein by reference in its entirety.

### BACKGROUND

### (a) Field

The subject matter disclosed generally relates to energy storage solutions and energy management. More particularly, the subject matter disclosed relates to energy storage solutions and electric energy management for vehicles.

### (b) Related Prior Art

Electrical energy storage systems are commonly employed on mobile vehicles such as heavy-duty trucks (semi-trucks) and other industrial motorized equipment and so too are applications that require additional electrical energy storage. As such, many variations have been envisioned and implemented in practice. One common method is to connect multiple electrical storage elements with an electrically parallel circuit where a primary energy storage system (which may consist of a group of one or more smaller electrical storage elements) has the same or nearly the same applied voltage as a secondary or auxiliary storage system (which may also consist of a group of one or more smaller electrical storage elements) and both the primary and secondary energy storage systems charge and discharge in unison. In this implementation scheme, additional electrical storage elements may be simply added with parallel electrical connection in a cascade fashion to the primary storage system and thereby increase the overall energy storage capacity. When implemented poorly, an auxiliary energy storage system of this style can overtax the system supply of electrical energy and accelerate wear on the electrical energy alternator or generator. Additionally, when electrical storage elements are passively connected in a parallel circuit, it will not be possible to adjust the charging and discharging of each storage element or battery according to the individual needs of each energy storage element. In this case, the overall energy cycle life or energy throughput of the energy storage system may not be as high as it could possibly achieve when better control is applied to individual elements within the overall energy storage system.

In view of this situation, there is therefore a need for improvement.

### SUMMARY

In some aspects, the description herein relates to a vehicle including: a plurality of Electric Energy Storage Components (EESCs) including a Main EESC (MEESC) adapted to store electric energy and feed electric power according to a first voltage range, and an Auxiliary EESC (AEESC) adapted to store electric energy and feed electric power according to a second voltage range; monitoring means associated with the EESC's; a DC/DC converter adapted to convert electric power between the first voltage range and the second voltage range; electric circuit coupling the EESC's and the DC/DC converter; and a controller coupled to the monitoring means, the controller adapted to generate and transmit a signal to the DC\DC converter thereby regulating transfer of electric power between the EESC's.

In some aspects, the description herein relates to a vehicle, further including at least one accessory device source of an accessory load, wherein the vehicle is adapted to power the accessory load regardless of the vehicle being in an idle state or not.

In some aspects, the description herein relates to a vehicle, wherein the circuit is adapted for either one of the MEESC and the AEESC powering the accessory load.

In some aspects, the description herein relates to a vehicle, further including an engine and an alternator, wherein the controller is adapted to have the alternator charging at least one of the EESC's.

In some aspects, the description herein relates to a vehicle, wherein the vehicle includes an Electronic Control Unit (ECU), wherein the controller is distinct from the ECU.

In some aspects, the description herein relates to a vehicle, wherein at least one of the monitoring means monitors at least one of i) voltage and ii) amperage.

In some aspects, the description herein relates to a vehicle, wherein the first voltage range is lower than the second voltage range.

In some aspects, the description herein relates to a vehicle, further including electrical flow controlling means (EFCM) to selectively control flow of electric power to and from EESC's.

In some aspects, the description herein relates to a vehicle, wherein the EFCM is incorporated into the DC/DC converter.

In some aspects, the description herein relates to a vehicle, wherein the accessory device is at least one of a heating device and a cooling device.

In some aspects, the description herein relates to a vehicle, wherein the accessory device is a Heating, Ventilation and Air Conditioning system (HVAC).

In some aspects, the description herein relates to a vehicle, wherein the at least one of the EESC's includes at least one of a) a battery, b) a capacitor, c) a hybrid capacitor, and d) an ultra-capacitor.

In some aspects, the description herein relates to a method, further including powering an accessory load using electric power transmitted by at least one of the plurality of EESC's.

In some aspects, the description herein relates to a method, further including setting ratios of electric power powering the accessory load between the electric power transmitted by the MEESC and the electric power transmitted by the AEESC.

In some aspects, the description herein relates to a method, further including dynamically varying the ratios.

In some aspects, the description herein relates to a method, further including having a first one of the plurality of EESC's powering simultaneously i) an accessory load and ii) a second one of the plurality EESC's, thereby charging the second one of the plurality of EESC's.

In some aspects, the description herein relates to a method, further including powering the accessory load regardless of the vehicle being in an idle state or not.

In some aspects, the description herein relates to a method, wherein the vehicle includes an auto-start module coupled to an engine and wherein the auto-start module starts the engine when the MEESC is depleted to a Discharge Rating (DR), the method including the controller signaling the DC/DC converter to have the MEESC transferring electric power to the AEESC down to the DR of the MEESC, thereby having the auto-start module starting the engine of the vehicle.

In some aspects, the description herein relates to a method, wherein the vehicle includes an engine and an alternator generating electric power when the engine is running, wherein the method includes having the DC/DC converter modulating ratios of the electric power generated by the alternator used to charge the MEESC and the AEESC.

Features and advantages of the subject matter hereof will become more apparent in light of the following detailed description of selected embodiments, as illustrated in the accompanying figures. As will be realized, the subject matter disclosed and claimed is capable of modifications in various respects, all without departing from the scope of the claims. Accordingly, the drawings and the description are to be regarded as illustrative in nature and not as restrictive and the full scope of the subject matter is set forth in the claims.

### BRIEF DESCRIPTION OF THE DRAWINGS

Further features and advantages of the present disclosure will become apparent from the following detailed description, taken in combination with the appended drawings, in which:

FIG. 1 is a representation of a vehicle electric system that implements the object of the invention in accordance with an embodiment;

FIG. 2 is a table of states exhibited by the vehicle electric system, and response of the vehicle electric system to these states in accordance with an embodiment;

FIG. 3 is a graph depicting evolution of voltage relative to the State of Charge (SoC) charge cycle and discharge cycle of a primary energy storage in accordance with another embodiment;

FIG. 4 is a graph depicting an evolution of the SoC of the primary energy storage, the voltage at the poles of the primary energy storage, and the SoC of the auxiliary energy storage in accordance with an embodiment; and

FIG. 5 is another representation of a vehicle electric system that implements the object of the invention in accordance with another embodiment.

It will be noted that throughout the appended drawings, when present identical features are identified by like reference numerals.

### DETAILED DESCRIPTION

The realizations will now be described more fully hereinafter with reference to the accompanying figures, in which realizations are illustrated. The foregoing may, however, be embodied in many different forms and should not be construed as limited to the illustrated realizations set forth herein.

With respect to the present description, references to items in the singular should be understood to include items in the plural, and vice versa, unless explicitly stated otherwise or clear from the text. Grammatical conjunctions are intended to express any and all disjunctive and conjunctive combinations of conjoined clauses, sentences, words, and the like, unless otherwise stated or clear from the context. Thus, the term “or” should generally be understood to mean “and/or” and so forth.

Recitation of ranges of values and of values herein or on the drawings are not intended to be limiting, referring instead individually to any and all values falling within the range, unless otherwise indicated herein, and each separate value within such a range is incorporated into the specification as if it were individually recited herein. The use of any and all examples, or exemplary language (“e.g.,” “such as”, or the like) provided herein, is intended merely to better illuminate the exemplary realizations and does not pose a limitation on the scope of the realizations. No language in the specification should be construed as indicating any unclaimed element as essential to the practice of the realizations. The use of the term “substantially” is intended to mean “for the most part” or “essentially” depending on the context. It is to be construed as indicating that some deviation from the word it qualifies is acceptable as would be appreciated by one of ordinary skill in the art to operate satisfactorily for the intended purpose.

In the following description, it is understood that terms such as “first”, “second”, “top”, “bottom”, “above”, “below”, and the like, are words of convenience and are not to be construed as limiting terms.

### Lexicon

For easing the reading of the present documents, the following lexicon and associated abbreviations are used hereinafter:
ECU: Electronic Controller Unit of the vehicle.
ICE: Internal Combustion Engine of the vehicle operating on e.g., fossil fuel or other type of fuel. Also contemplated are other engines relying on fuel consumption.
Alternator: device transforming mechanical work provided by the ICE into electric power. According to embodiments, the alternator is distinct from the ICE, but according to contemplated embodiments, the alternator may be integrated in the ICE, relying or not on mechanical work transformed into electric power. According to embodiment, the alternator may include sensors and controller, thereby being a smart alternator without departing from the scope of the present description.
EESC: Electric Energy Storage Component adapted to store electric energy, such as one or more electrochemical battery. Other means for storing more or less permanently electric energy are also intended to be encompassed by this expression.
MEESC: Main Electric Energy Storage Component (Main EESC) or other primary or main electric energy storage solution used to start the ICE of the vehicle. Such MEESC is typically one or more electrochemical battery.
Accessory load: electric load generated by one or multiple components of the vehicle operating on electric power, distinct from the vehicle operative components, such as a heating device, a cooling device, an air circulating device, or a Heating, Ventilation and Air Conditioning system (HVAC) distinct from vehicle's operating components. Accessory component is intended to encompass any electrically powered device including for occupant safety, comfort, recreation and to fulfill job function. Examples include entertainment devices, communication equipment, cooking appliances, personal use refrigerator/freezer, CPAP, device chargers.
AEESC: Auxiliary Electric Energy Storage Component (Auxiliary EESC) or other auxiliary electric energy storage solution used in combination with the MEESC. The AEESC is typically one or more electrochemical batteries, but may be or consist or comprise a capacitor, a hybrid capacitor, or an ultra capacitor.
SoC: State of Charge of an electric energy storage Component, e.g., battery pack, providing an indication of potential energy stored in the battery pack at precise instant; the SoC being more precisely the MEESC-SoC when indicative of the SoC of the MEESC, and the AEESC-SoC when indicative of the SoC of the AEESC. According to embodiments, a more or less precise SoC may be provided with sensors and computing capability, or a measurement of e.g., output voltage without departing from the scope of the present description.
Monitoring means: device or method used to provide indication of a SoC or condition of operation of an electric energy storage component (EESC), such as a voltage meter or a current meter. According to embodiments, a monitoring means may be almost not invasive, such as a voltage sensor, to a complex subsystem integrated to an EESC comprising e.g., a set of sensors and a dedicated controller. For the present description, monitoring means should be understood as any monitoring device providing at least a broad indication of the SoC or condition of operation of an EESC.
DC/DC converter: device adapted to convert an electric power, more precisely current between a first voltage range and a second voltage range, wherein the DC/DC converter can be adapted to perform conversion in both directions.
Electrical Flow Controlling Means (EFCM): Electrical Flow Controlling Means (EFCM) are controllable switches or other devices that are adapted to selectively control and modify a circuit, thus selectively control flow of electric power to and from the MEESC and the AEESC, including means to open or close a circuit, or a portion of a circuit to electrically connect or disconnect components to one another. Unless clear from the description, in the description the term “switch” is intended to mean a “controllable switch” such as a MOSFETS that are operated based on signals from a controller.

### Description

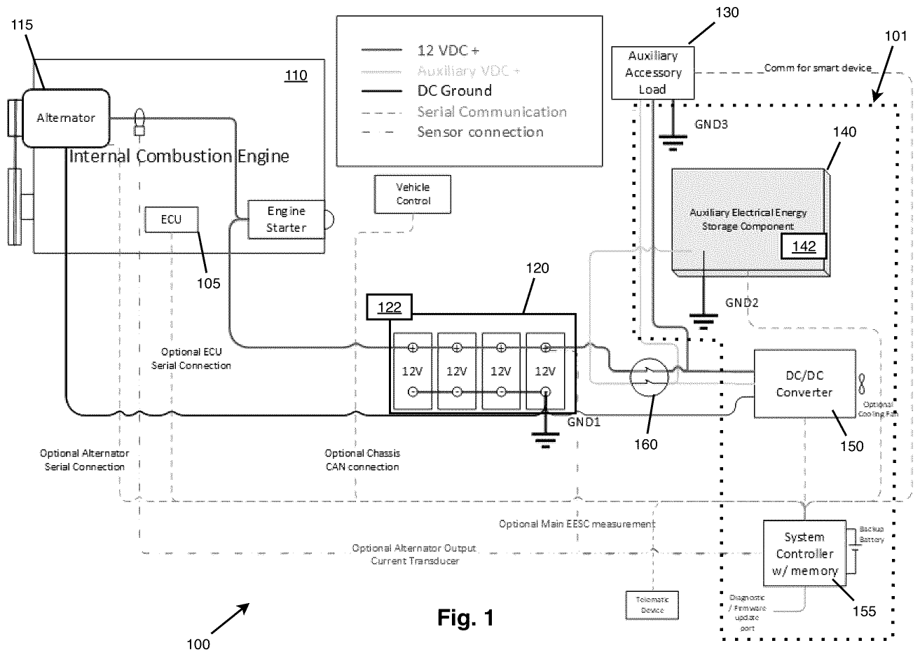

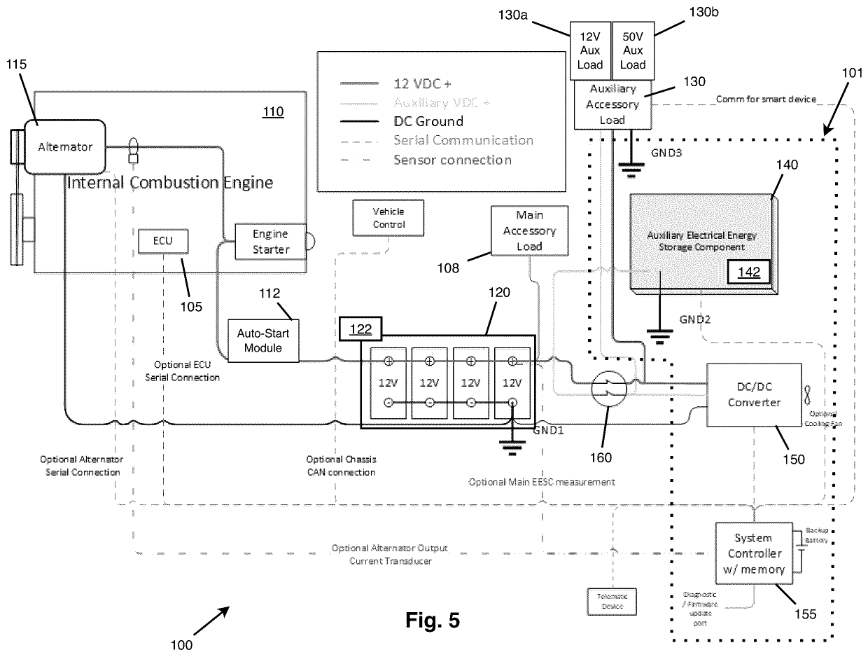

The present description is drawn to a novel auxiliary electric energy storage system 101 (see FIG. 1 and FIG. 5) designed to provide support to the primary energy storage in a minimum invasive manner. In an embodiment, the novel auxiliary electric energy storage system 101 comprises the AEESC; monitoring components (e.g., voltage sensors, current sensors) or inputs reflecting a monitoring process; a controller; and a DC/DC converter. The DC/DC converter controls the components feeding energy to the auxiliary load, providing controlled depletion of the MEESC and the AEESC, with the controlled depletion being used as an indirect method for ensuring that the OEM system of the vehicle is initiating the ICE when MEESC-SoC decreases to an ICE start point. According to an embodiment, the DC/DC converter may comprise internal switches involved in increasing voltage, decreasing voltage, or electrically isolating components, e.g., MEESC, AEESC and itself.

The present description is drawn to a novel auxiliary electrical energy storage system 101 designed to provide support to the primary energy storage, in certain circumstances, when the need for electrical energy storage in an application has increased above the original design intent of a main electric energy storage component. The auxiliary electrical energy storage system 101 is designed to supplement the primary electrical energy storage component, wherein the auxiliary electrical energy storage system 101 may be added to an existing vehicle retrofitting the original design and configuration of the primary energy storage component or of the vehicle in general. The auxiliary electrical energy storage system 101 does not harm or limit the functionality of the primary energy storage components and can enhance the overall performance and life of the primary electrical energy storage component while also supplying additional electrical energy for increased or long-lived electrical loads.

In embodiments, the present description particularly aims large vehicles or other equipment adapted to operate with extended idling phases such as, without limitation, semi-trucks, service vehicles such as police vehicles, fire trucks, ambulances, wherein the vehicles or equipment usually comprise a large main energy conversion device like an engine or fuel cell where the large energy conversion device provides both energy sources to perform the main intended task such as carrying a load down a road and producing power for onboard auxiliary electric loads. When the primary function is not required but the accessory load function is required, the auxiliary electrical energy storage system 101 is able to extend the functionality of the auxiliary accessory and thereby reduce the need for the large energy conversion device from being engaged. An example is a large vehicle where the engine has enough energy to propel the vehicle down the road to perform a primary function and also to charge one or more of the EESC's simultaneously. When the truck is parked, stored electrical energy in the primary batteries, e.g., MEESC, and auxiliary batteries, e.g., AEESC, of the vehicle described by the invention is sufficient to maintain cabin comfort while the driver or occupant is resting without engaging the main engine of the vehicle or with the engine being limitedly engaged.

Referring to FIG. 1, according to an embodiment the electrical energy management system 100 of the present vehicle comprises base components that are an ECU 105; an ICE 110 controlled by the ECU 105; an alternator 115 coupled to the ICE 110, the alternator 115 generating electric power during operation of the ICE 110; a MEESC 120 having a monitoring means 122, e.g., a voltage sensor, incorporated therein, associated therewith or coupled thereto to detect a state of the MEESC, the MEESC 120 being adapted to store and feed electric power according to a first voltage range; and an accessory load 130 generating an electric load in the electric energy management system 100, with the accessory load 130 being dedicated to e.g., maintaining the cabin of the vehicle in comfortable conditions when the ICE 110 is On as when the ICE 110 is Off. The electric energy management system 100 further comprises an auxiliary electric energy management system 101 that comprises an AEESC 140, a DC/DC converter 150, and a controller 155 operating according to instruction codes. It is to be noted that according to embodiments, the controller 155 may be physically limited to a single component or distributed over different components. The electrical energy management system 100 further comprises or operates in association with sensors, e.g. sensors 122, 142, dedicated to e.g., the MEESC 120, the AEESC 140, and measuring electric load such as the one generated by the accessory load 130. The electrical energy management system 100 may comprise switches, preferably integrated into the DC/DC converter, but also potentially, non-mandatory, disposed over the circuit, e.g. switches 160, allowing to control the circuit, such as selectively isolating the MEESC 120 and the AEESC 140. FIG. 1 schematically depicts the electrical connection between the components of the electrical energy management system 100, including the existing or typical components of the vehicle of the present example. A person skilled in the art would recognize from the schematic of FIG. 1, associated with the examples of operations described in the present document, the functionalities of the electrical energy management system 100.

FIG. 5 is an enriched embodiment compared to FIG. 1. FIG. 5 schematically depicts a low intrusive system 100 in which an auxiliary electrical energy management system 101 takes advantage of existing components of the vehicle, with the auxiliary load 130 comprising a combination of 12 volts auxiliary load 130a and of 50 volts auxiliary load 130b adapted to be powered by the MEESC 120, and AEESC 140. FIG. 5 further illustrates an electric load 108 associated with components of the vehicle that requires permanent powering, powered by the circuit coupled to the MEESC 120. The embodiment of FIG. 5 differs further from the embodiment of FIG. 1 in the vehicle comprising an auto-start module 112 that, when in the automatic start mode, automatically starts the ICE 110 whenever the voltage of the MEESC 120 decreases to an engine start value or the start module receives a signal that MEESC is at or below its Discharge Rating (DR). With this embodiment, the auxiliary electrical energy management system 101 in an unintrusive indirect manner is able to start the ICE 110 by controllably depleting the charge of the MEESC, without having to connect to the auto-start module 112, or the ECU 115, applicable, for instance, when retrofitting an existing vehicle with the auxiliary electric energy management system 101.

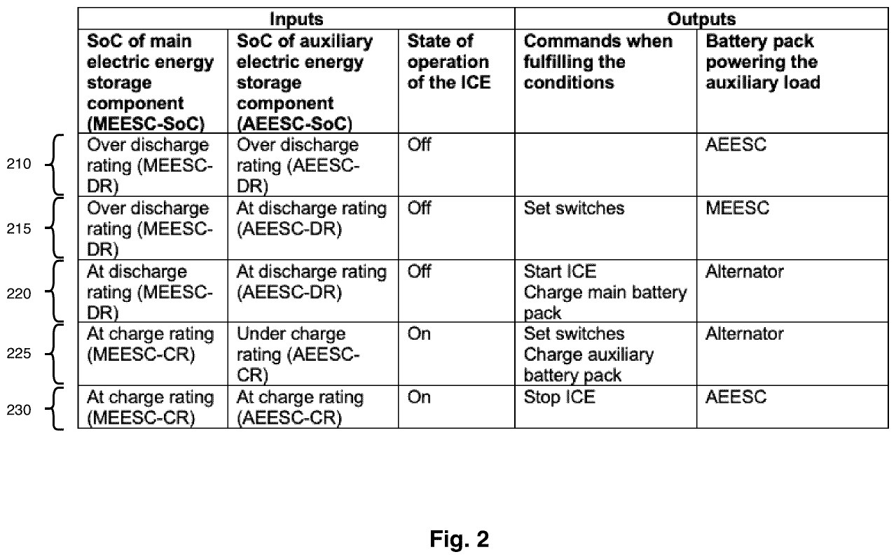

Referring to FIG. 2, the electrical energy management system 100 of the vehicle is designed to operate according to different conditions. For the present example, the MEESC 120 is designed to operate according to a voltage range around 12 volts, and the AEESC 140 is designed to operate according to a voltage range around 50 volts. Most of the accessory load 130 is designed to be powered with current at the 50 volts range. Conditions of operation of the electrical energy management system 100 are indicated by the rows of the table of FIG. 2.

Row 210 represents a state in which the vehicle stops after a run. The MEESC 120 and the AEESC 140 are appropriately or fully charged. The driver after the run needs to rest before continuing, requiring the accessory load 130 to operate to keep the cabin of the vehicle in a comfortable zone. After the ICE 110 is stopped, the electrical energy management system 100 operates by having the accessory load 130 powered by the AEESC 140.

Row 215 represents a state in which after a while the AEESC 140 has discharged down to a trigger discharge rating (DR) associated with the AEESC 140, an AEESC-DR. When the AEESC-DR is reached, the controller 155 considers that the AEESC 140 does not store enough energy to maintain powering the accessory load 130. The controller 155 then directs the DC/DC converter 150 to boost up the voltage of the MEESC to a voltage equal to or greater than the voltage of the AEESC 140 such that electrical energy can flow from the MEESC 120 to the accessory load 130 without further depleting the energy of the AEESC 140.

Row 220 represents a state in which the MEESC 120 also discharged to a discharge rating (MEESC-DR) where continuing powering the accessory load 130 with the MEESC 120 would put at risk the capacity of the MEESC 120 to start the ICE 110. At this situation, OEM system of the vehicle, if set at auto-start, triggers the ICE 110 to start. Through the present description, it is also contemplated detecting whether the ICE's auto-starting feature of the vehicle has been engaged or not. When the Auto Start feature is active, the DR rating of the MEESC 120 may be set to a lower value then when the Auto Start is not active. Furthermore, in embodiments with monitoring means to evaluate engine or ambient temperature, the DR rating of the MEESC 120 may be adjusted, e.g., lowered with hot engine or warmer ambient temperature. When the Auto Start is engaged and the engine is warm, the DR may be set to its lowest value thereby providing maximum engine off time.

It is worth noting that in an almost unintrusive manner, in order to limit intrusion to the OEM system of a vehicle, the controller 155 of the electric energy management system 100 is designed to controllably deplete the MEESC 120 to the ICE start point by, e.g., charging the AEESC 140. Thus, without having access to the ECU, the controller 155 is able to set the vehicle in an ICE start condition, allowing complex optimization of the management of the electric energy storage of the vehicle.

Back to row 220, the ICE 110 being started, the alternator 115 starts generating electric energy that is used to power the accessory load 130 and recharge the MEESC 120. It is worth mentioning that in this state, the DC/DC converter 150 may continue boosting the voltage to power the accessory load 130.

Row 225 represents a state in which after a while the MEESC 120 has reached a charge rating (MEESC-CR) the controller 155 sets the operating condition to charge the AEESC 140. The voltage in that state is boosted by the DC/DC converter 150 both to charge the AEESC 140 and power the accessory load 130.

Row 230 represents a state in which the AEESC reaches a charge rating (AEESC-CR). Thus, both MEESC 120 and AEESC 140 are charged. The controller 155 may then direct the ECU 105 to stop the ICE 110, limiting combustion of fossil fuel. According to embodiments, the ECU 150 being stopped may be according to OEM system and configuration such as the ICE 110 being programmed to operate a fixed time period, e.g. 1 hour, an estimated MEESC SoC based on an OEM method or, the ICE 110 stopping being based on other conditions.

Following row 230, the vehicle comes back to the state of row 210 or at least, a state where both the MEESC and AEESC have accumulated sufficient charge to sustain operation of the accessory load and ensure the ICE can restart when required.

It is worth noting that any state may be interrupted by the driver starting the vehicle. Since the MEESC 120 is never depleted of energy less than a safe SoC for starting the ICE 110, this condition may be initiated at any time, not restricting the driver from operating the vehicle.

It is worth noting that the auxiliary electric energy management system 101 being integrated preferably in an unintrusive manner with the native equipment of the vehicle in a retrofitted exemplary embodiment, the auxiliary electric energy management system 101 keeps operating after the vehicle being started, e.g., being able to charge the AEESC 140 as the vehicle is travelling.

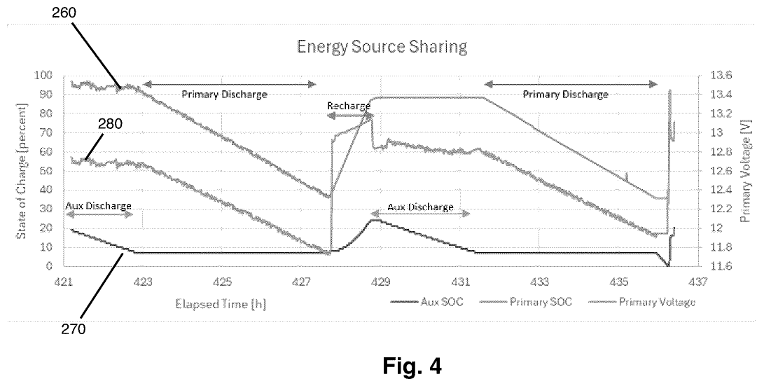

According to an exemplary realization with support of FIG. 4, there is a described situation in which MEESC voltage used for the vehicle and the low voltage accessories of the vehicle, not to be confused with the HVAC cabin comfort accessories, an exemplary accessory load, wherein the AEESC-DR is set limit to 7% SoC. Reference 260 represents the SoC of the MEESC 120 over discharge and charge cycles. Reference 270 represents the evolution of the SoC of the AEESC 140 over discharge and charge cycles. Reference 280 represents the voltage available to the vehicle components, the low voltage vehicle components, and other electric needs over the discharge and charge cycles, thus in other words for vehicle essential components.

When an electrical source becomes available, at least a ratio of the electrical energy is used to charge the MEESC 120 and power the electrical load of the accessory load 130. As the need for charging the MEESC 120 is reduced and assuming the electrical source energy level and the auxiliary energy level remain constant, more of the electrical source energy can be channeled into charging the AEESC 140. When the source energy is no longer available, the electric energy management system 100 returns to the original state where the external accessory load 130 withdraws electrical energy from the AEESC 140 until the AEESC 140 reaches a low threshold SoC (AEESC-DR) and the DC/DC converter 150 is engaged to a level sufficient to withdraw electrical energy from the MEESC 120 at a rate that equals or nearly equals the rate of electrical energy consumption of the electrical load of the accessory load 130. In this manner, the AEESC 140 neither gains nor loses electrical charge but the accessory load 130 operates without interruption until an end state occurs. An end state can be reached by depleting the SoC or attaining a cutoff voltage from the MEESC 120 and depleting the SoC of the AEESC 140. It is worth mentioning that various conditions and calculations may be considered to determine the conditions for determining the ratios as the evolutions of the ratios, such as the SoC's, characteristics of components of the systems, environmental conditions, and intended or determined behavioral conditions.

An advantage of this method of managing electric energy can ensure that the AEESC 140 is depleted or nearly depleted before making use of the MEESC 120. The electrical load generated by the accessory load 130 on the MEESC 120 is lowered. By modulating the rate of energy withdraw from the MEESC 120, the battery life cycles can be extended. Also, irrecoverable losses are associated when charging and discharging EESC, so this method aims to limit charging and discharging losses and increases available energy for the accessory load 130.

According to an embodiment, a hybrid charge strategy may be designed for the accessory load 130 to be powered by the AEESC 140 until the AEESC 140 reaches a threshold of 25% for example. At this point, the DC/DC converter 150 is engaged, and the accessory load 130 is powered by a portion of electrical energy from the AEESC 140 and also by the MEESC 120. Blending electric energy from both the MEESC 120 and the AEESC 140 may either be performed at a preset rating such as 50% from the AEESC 140 and 50% from the MEESC 120, or it can be dynamically modulated, resulting in a modulable variable rating such that the blend of electrical energy starts with an important ratio of energy from the AEESC 140 and progressively increases to the MEESC 120 as the AEESC 140 is depleted.

This control method available with the AEESC 140 potentially has the advantage of having low electrical losses and potentially high amount of electrical energy available for the accessory load 130.

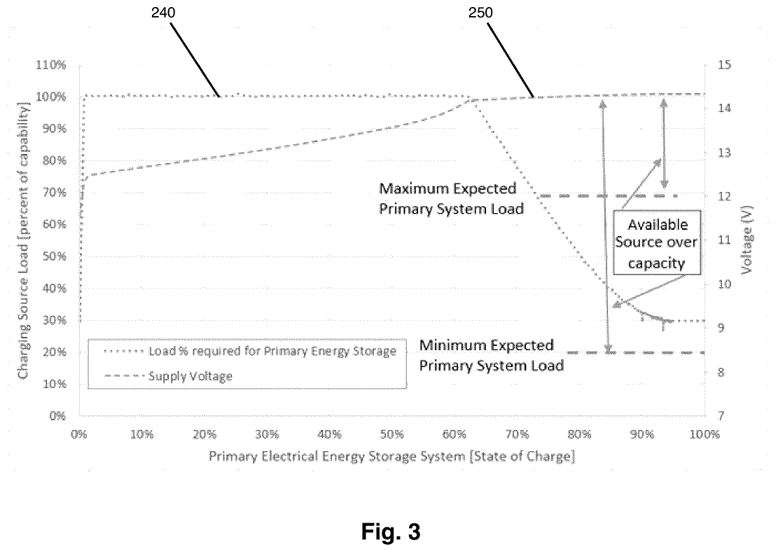

FIG. 3 shows the evolution of the percentage of the alternator output used to supply the MESSC and vehicle baseline electrical load over time. Reference 240 represents the percentage of the electric power used to charge the MEESC 120 and power a relatively low vehicle primary system electric load, showing that this percentage decreases when the SoC of the MEESC 120 reaches a certain value. Reference 250 represents the evolution of voltage available as the MESSC SoC increases and maximum output of the alternator 115 is fixed.

As can be observed, the maximum output of the alternator 115 can be used to charge the MEESC 120 and supply energy for the vehicle base load until the MEESC-SoC reaches a percentage about 62% in that example. Following that point, extra electric load can be used for other function, such as charging the AEESC 140. Setting of the conditions setting ratios according to which the MEESC 120 and the AEESC 140 are charged, as the ratios according to which they are powering the accessory load 130 can be based on equipment characteristics, allows potential optimization of the consumption of fossil fuel and a potential extent of the life cycle of the MEESC 120 and of the AEESC 140.

Tests have demonstrated that the present electric energy management system 100 can provide improvements over electric systems of vehicles available nowadays, wherein the improvements are both in decreasing the number of start engine cycles that generate most of the environmentally harmful gas at the initiation of the cycle, and improving the life cycles of the batteries of vehicles. Practically, the tests demonstrated that the period between the ICE starts with the same storage capacity were delayed from e.g., about 2.5 hours between them to about 4 hours, and in some circumstances can be delayed even up to 36 hours between them, resulting in decrease of discharge of harmful gas into the environment.

It is further worth mentioning that the electric energy stored in the AEESC 140 can be used to jump-start the engine. Electric power transfer between the MEESC 120 and the AEESC 140 allow innovative response to other situations not described herein.

While preferred embodiments have been described above and illustrated in the accompanying drawings, it will be evident to those skilled in the art that modifications may be made without departing from this disclosure. Such modifications are considered as possible variants comprised in the scope of the disclosure.

1. A vehicle comprising:
a plurality of Electric Energy Storage Components (EESCs) comprising a Main EESC (MEESC) adapted to store electric energy and feed electric power according to a first voltage range, and an Auxiliary EESC (AEESC) adapted to store electric energy and feed electric power according to a second voltage range;
monitoring means associated with the EESC's;
a DC/DC converter adapted to convert electric power between the first voltage range and the second voltage range;
electric circuit coupling the EESC's and the DC/DC converter; and
a controller coupled to the monitoring means, the controller adapted to generate and transmit a signal to the DC/DC converter thereby regulating transfer of electric energy between the EESC's.

2. The vehicle of claim 1, further comprising at least one accessory device source of an accessory load, wherein the vehicle is adapted to power the accessory load regardless of a vehicle engine being in an operational state or not.

3. The vehicle of claim 2, wherein the circuit is adapted for either one of the MEESC and the AEESC powering the accessory load.

4. The vehicle of claim 1, further comprising an engine and an alternator, wherein the controller is adapted to have the alternator charging at least one of the EESC's.

5. The vehicle of claim 1, wherein the vehicle comprises an Electronic Control Unit (ECU), wherein the controller is distinct from the ECU.

6. The vehicle of claim 1, wherein at least one of the monitoring means monitors at least one of i) voltage and ii) amperage.

7. The vehicle of claim 1, wherein the first voltage range is lower than the second voltage range.

8. The vehicle of claim 1, further comprising electrical flow controlling means (EFCM) to selectively control flow of electric energy to and from EESC's.

9. The vehicle of claim 8, wherein the EFCM is incorporated into the DC/DC converter.

10. The vehicle of claim 2, wherein the accessory device is at least one of a heating device, a cooling device and an air circulating device.

11. The vehicle of claim 2, wherein the accessory device is a Heating, Ventilation and Air Conditioning system (HVAC).

12. The vehicle of claim 1, wherein the at least one of the EESC's comprises at least one of a) a battery, b) a capacitor, c) a hybrid capacitor, and d) an ultra-capacitor.

13. A method of managing electric energy of a vehicle comprising:
a plurality of Electric Energy Storage Components (EESCs) comprising a Main EESC (MEESC) adapted to store electric energy and feed electric power according to a first voltage range, and an Auxiliary EESC (AEESC) adapted to store electric energy and feed electric power according to a second voltage range;
monitoring means associated with the EESC's;
a DC/DC converter adapted to convert electric power between the first voltage range and the second voltage range;
electric circuit coupling the EESC's and the DC/DC converter; and
a controller coupled to the DC/DC converter, the method comprising:
monitoring states of the EESC's;
according at least to the states of the EESC's, having the controller generating and transmitting a signal the DC/DC converter,
based on the signal, having the DC/DC converter modulating energy transfer between the MEESC and the AEESC,
whereby the method controls source and voltage of electric power transmitted by the EESC's.

14. The method of claim 13, further comprising powering an accessory load using electric power transmitted by at least one of the plurality of EESC's.

15. The method of claim 14, further comprising setting ratios of electric power powering the accessory load between the electric power transmitted by the MEESC and the electric power transmitted by the AEESC.

16. The method of claim 15, further comprising dynamically varying the ratios.

17. The method of claim 13, further comprising having a first one of the plurality of EESC's powering simultaneously i) an accessory load and ii) a second one of the plurality EESC's, thereby charging the second one of the plurality of EESC's.

18. The method of claim 14, further comprising power the accessory load regardless of a vehicle engine being in an operational state or not.

19. The method of claim 13, wherein the vehicle comprises an auto-start module coupled to an engine and wherein the auto-start module starts the engine when the MEESC is depleted to a Discharge Rating (DR), the method comprising the controller signaling the DC/DC converter to have the MEESC transferring electric power to the AEESC down to the DR of the MEESC, thereby having the auto-start module starting the engine of the vehicle.

20. The method of claim 13, wherein the vehicle comprises an engine and an alternator generating electric power when the engine is running, wherein the method comprises to having the DC/DC converter that modulates ratios of the electric power generated by the alternator used to charge the MEESC and the AEESC.
